(19) United States
(12) Patent Application Publication
(10) Pub. No.: US 2020/0072564 A1
(43) Pub. Date: Mar. 5, 2020

(54) THERMAL SWITCH, METHOD FOR MANUFACTURING THERMAL SWITCH, THERMALLY CONDUCTIVE FILLER-CONTAINING COMPOSITE MATERIAL, APPARATUS CONTAINING THE COMPOSITE MATERIAL, AND DISPLAY DEVICE

(71) Applicant: Sharp Kabushiki Kaisha, Sakai City (JP)

(72) Inventors: Yasuhiro HASEBA, Sakai City (JP); Kiyoshi MINOURA, Sakai City (JP)

(21) Appl. No.: 16/548,888

(22) Filed: Aug. 23, 2019

Related U.S. Application Data
(60) Provisional application No. 62/725,379, filed on Aug. 31, 2018.

(51) Int. Cl. F28F 13/00; H05K 7/20

(52) U.S. Cl. CPC F28F 13/00; F28F 2013/008; H05K 7/20963

(57) ABSTRACT

[Object] To enable a thermal switch (7), having high durability, capable of controlling the thermal conductivity by an electric field (E) to be achieved.

[Solution] A composite material (COM) which is deformed by an electric field (E) formed between a lower electrode (2) and an upper electrode (6) and which contains a polymer material (PO) and a liquid crystal material (LC) and a low-thermal conductivity medium (4) with a thermal conductivity lower than the thermal conductivity of the composite material (COM) when the thermal switch (7) is ON are placed between a heatsink (11) which is a first member and a heat source (10) which is a second member in a thermal switch (7).

### TECHNICAL FIELD

The present disclosure relates to a thermal switch, a method for manufacturing the thermal switch, a thermally conductive filler-containing composite material, an apparatus containing the composite material, and a display device.

### BACKGROUND ART

Non Patent Literature 1 below describes a cooling device in which the electric dipole moment of a substance is controlled by an electric field and an electrocaloric element itself having an electrocaloric effect causing the release or absorption of heat due to a change in entropy functions as an actuator. In the cooling device, when the electrocaloric element is in contact with a heatsink, an electric field is applied to the electrocaloric element to generate heat and the heat of the electrocaloric element is transferred to the heatsink. On the other hand, when the electrocaloric element is in contact with a heat source, an electric field is removed from the electrocaloric element such that the electrocaloric element enters an endothermic state and heat is transferred from the heat source to the electrocaloric element. The cooling device can cool the heat source by repeating this cycle.

Non Patent Literature 2 below describes the electrocaloric effect of a liquid crystal material usable in the electrocaloric element having the electrocaloric effect or a composite material of a polymer material and the liquid crystal material. It is described that a liquid crystal alone (5CB alone) exhibits an electrocaloric effect favorably comparable with that of P (VDF-TrFE-CFE), which is known to exhibit a large electrocaloric effect (ΔT or ΔS is large). Furthermore, it is described that PSLC (polymer stabilized LC), which exhibits less ΔS as compared to the liquid crystal alone, has a wide temperature range in which a large electrocaloric effect is exhibited.

### CITATION LIST

### Non Patent Literature

[Non Patent Literature 1] Ma et al., “Highly efficient electrocaloric cooling with electrostatic actuation”, Science 357, 1130-1134, (15 Sep. 2017).
[Non Patent Literature 2] A Dissertation in Department of Electrical Engineering by Xiaoshi Qian (August 2015). “MATERIAL SYSTEM ENGINEERING FOR ADVANCED ELECTROCALORIC COOLING TECHNOLOGY”, The Pennsylvania State University The Graduate School Department or Electrical Engineering.

### SUMMARY OF INVENTION

### Technical Problem

However, in the case of the cooling device described in Non Patent Literature 1, in order to cool the heat source, a portion of the electrocaloric element needs to be repeatedly moved between the heatsink and the heat source. That is, in the case of the cooling device described in Non Patent Literature 1, an electric field needs to be repeatedly applied to or removed from the electrocaloric element while the heat source is being cooled.

Thus, in the case of the cooling device described in Non Patent Literature 1, there is a significant problem with durability because a bent portion is formed in the electrocaloric element when a portion of the electrocaloric element is repeatedly moved.

In the case of an electrocaloric element containing the liquid crystal material described in Non Patent Literature 2 or the composite material of the polymer material and the liquid crystal material, there is a problem in that the difference in thermal conductivity of the electrocaloric element between the presence and absence of an electric field is not enough to be satisfactory.

The present disclosure has been made in view of the above problems. It is an object of the present disclosure to provide a thermal switch, having high durability, capable of controlling the thermal conductivity by an electric field; a method for manufacturing the thermal switch; and a display device including the thermal switch. Furthermore, it is an object of the present disclosure to provide a thermally conductive filler-containing composite material capable of enhancing the difference in thermal conductivity of an electrocaloric element between the presence and absence of an electric field and an apparatus containing the thermally conductive filler-containing composite material.

### Solution to Problem

(1) An embodiment of the present invention is a thermal switch including a first member and second member placed so as to face each other. The thermal conductivity between the first member and the second member is higher during an ON period than during an OFF period. A composite material which is deformed by an electric field formed between a plurality of electrodes attached to at least one of the first member and the second member and which contains a polymer material and a liquid crystal material and a low-thermal conductivity medium with a thermal conductivity lower than the thermal conductivity of the composite material during the ON period are placed between the first member and the second member.

(2) An aspect of the present invention is the thermal switch in which the thermal conductivity between the first member and the second member is changed in such a manner that the low-thermal conductivity medium changes the area that maintains isolation between the first member and the second member by the deformation of the composite material in addition to the configuration of Item (1).

(3) An aspect of the present invention is the thermal switch in which the composite material contains a thermally conductive filler in addition to the configuration of Item (1) or (2).

(4) An aspect of the present invention is the thermal switch in which the liquid crystal material, which is contained in the composite material, in a liquid crystal state is such that the value of the dielectric constant anisotropy (A) is 30 or more in addition to the configuration of any one of Items (1) to (3).

(5) An aspect of the present invention is the thermal switch in which the liquid crystal material, which is contained in the composite material, is such that the change in relative dielectric constant a temperature change of 1° C. at a temperature between −40° C. and 200° C. is 0.5/° C. or more in addition to the configuration of any one of Items (1) to (4)

(6) An aspect of the present invention is the thermal switch in which the electrodes include a lower electrode and an upper electrode, the lower electrode is attached to the first member, and the upper electrode is attached to the second member in addition to the configuration of any one of Items (1) to (5).

(7) An aspect of the present invention is the thermal switch in which the electrodes include a first electrode and a second electrode and the first electrode and the second electrode are attached to at least one of the first member and the second member in addition to the configuration of any one of Items (1) to (5).

(8) An aspect of the present invention is the thermal switch in which the low-thermal conductivity medium is gas or silicone oil in addition to the configuration of any one of Items (1) to (7).

(9) An aspect of the present invention is the thermal switch in which the thermally conductive filler is aluminum nitride particles in addition to the configuration of Item (3).

(10) An aspect of the present invention is the thermal switch in which one of the first member and the second member is a heat source and the other of the first member and the second member is a heatsink in addition to the configuration of any one of Items (1) to (9).

(11) An aspect of the present invention is the thermal switch in which the first member and the second member are bonded together with a sealing member therebetween and the composite material and the low-thermal conductivity medium are placed in a region which is located between the first member and the second member and which is surrounded by the sealing member in addition to the configuration of any one of Items (1) to (10).

(12) An embodiment of the present invention is a thermally conductive filler-containing composite material in which a composite material containing a polymer material PO and a liquid crystal material contains a thermally conductive filler.

(13) An aspect of the present invention is the thermal switch in which the composite material is deformed by an electric field in addition to the configuration of Item (12).

(14) An aspect of the present invention is the thermal switch in which the liquid crystal material in a liquid crystal state is such that the value of the dielectric constant anisotropy (Δε) is 30 or more in addition to the configuration of Item (12) or (13).

(15) An aspect of the present invention is the thermal switch in which the liquid crystal material is such that the change in relative dielectric constant a temperature change of 1° C. at a temperature between −40° C. and 200° C. is 0.5/° C. or more in addition to the configuration of any one of Items (12) to (14).

(16) An aspect of the present invention is the thermal switch in which the thermally conductive filler is aluminum nitride particles in addition to the configuration of any one of Items (12) to (15).

(17) An aspect of the present invention is an apparatus containing the thermally conductive filler-containing composite material specified in Item (12).

(18) An aspect of the present invention is a display device including the thermal switch specified in Item (1).

(19) An embodiment of the present invention is a method for manufacturing a thermal switch. The method includes a step of placing a first member and a second member such that the first member and the second member face each other, the thermal conductivity between the first member and the second member being higher during an ON period than during an OFF period, and a step of forming a composite material which is deformed by an electric field and which contains a polymer material and a liquid crystal material and a low-thermal conductivity medium with a thermal conductivity lower than the thermal conductivity of the composite material during the ON period on any one of the first member and the second member.

### Advantageous Effects of Invention

A thermal switch, having high durability, capable of controlling the thermal conductivity by an electric field; a method for manufacturing the thermal switch; and a display device including the thermal switch can be achieved.

Furthermore, a thermally conductive filler-containing composite material capable of enhancing the difference in thermal conductivity of an electrocaloric element between the presence and absence of an electric field and an apparatus containing the thermally conductive filler-containing composite material can be achieved.

### BRIEF DESCRIPTION OF DRAWINGS

FIG. 1A is an illustration showing a case where a thermal switch according to Embodiment 1 is in an OFF state (little heat transfer state) and FIG. 1B is an illustration showing a case where the thermal switch according to Embodiment 1 is in an ON state (much heat transfer state).

FIG. 2 is an illustration showing steps of manufacturing the thermal switch, shown in FIG. 1, according to Embodiment 1.

FIG. 3A is an illustration showing a case where another thermal switch according to Embodiment 1 is in an OFF state (little heat transfer state) and FIG. 3B is an illustration showing a case where the other thermal switch according to Embodiment 1 is in an ON state (much heat transfer state).

FIG. 4A is an illustration showing a case where another thermal switch according to Embodiment 1 is in an OFF state (little heat transfer state) and FIG. 4B is an illustration showing a case where the other thermal switch according to Embodiment 1 is in an ON state (much heat transfer state).

FIG. 5A is an illustration showing a case where a thermal switch according to Embodiment 2 is in an OFF state (little heat transfer state) and FIG. 5B is an illustration showing a case where the thermal switch according to Embodiment 2 is in an ON state (much heat transfer state).

FIG. 6 is an illustration showing steps of manufacturing the thermal switch, shown in FIG. 5, according to Embodiment 2.

FIG. 7A is an illustration showing a case where a thermal switch according to Embodiment 3 is in an OFF state (little heat transfer state) and FIG. 7B is an illustration showing a case where the thermal switch according to Embodiment 3 is in an ON state (much heat transfer state).

FIG. 8A is an illustration showing a case where a thermal switch according to Embodiment 4 is in an OFF state (little heat transfer state) and FIG. 8B is an illustration showing a case where the thermal switch according to Embodiment 4 is in an ON state (much heat transfer state).

FIG. 9A is an illustration showing a case where a thermal switch according to Embodiment 5 is in an OFF state (little heat transfer state) and FIG. 9B is an illustration showing a case where the thermal switch according to Embodiment 5 is in an ON state (much heat transfer state).

FIGS. 10A and 10B are illustrations showing the schematic configuration of a display device including the thermal switch, shown in FIG. 1, according to Embodiment 1.

### DESCRIPTION OF EMBODIMENTS

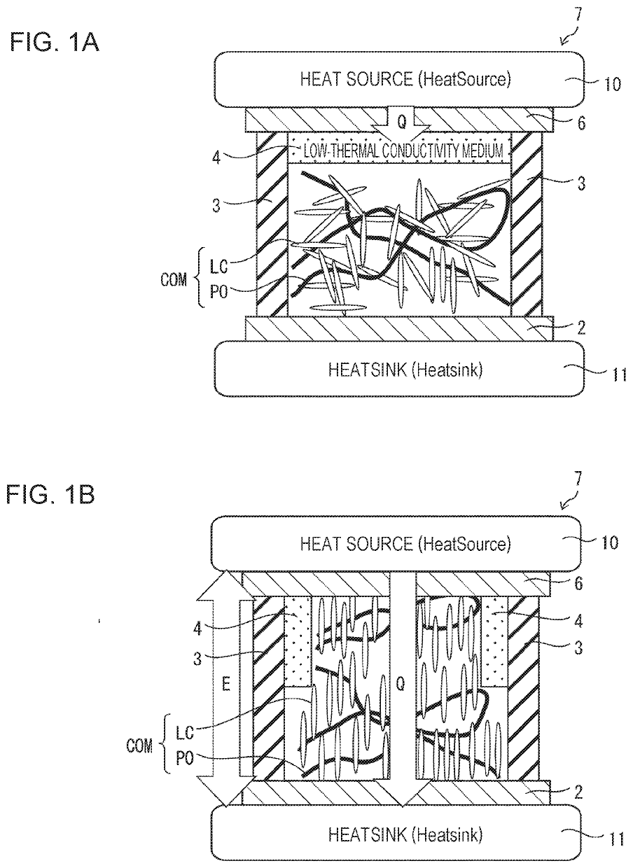

Embodiments of the present disclosure are described below with reference to FIGS. 1A to 9B. Hereinafter, for convenience of description, configurations having the same function as that of a configuration described in a specific embodiment are given the same reference numerals and will not be described in some cases.

### Embodiment 1

A thermal switch 7 according to Embodiment 1, a thermal switch 7a, and a thermal switch 7b are described below with reference to FIGS. 1A to 4B.

FIG. 1A is an illustration showing a case where the thermal switch 7 according to Embodiment 1 is in an OFF state (little heat transfer state). FIG. 1B is an illustration showing a case where the thermal switch 7 according to Embodiment 1 is in an ON state (much heat transfer state).

As shown in FIG. 1, the thermal switch 7 is a thermal switch in which the thermal conductivity between a heatsink 11 which is a first member and a heat source 10 which is a second member is higher during an ON period than during an OFF period. The thermal switch 7 includes a sealing member 3, the heat source 10, and the heatsink 11. The heat source 10 and the heatsink 11 are bonded together with the sealing member 3 therebetween so as to face each other. In a region which is located between the heat source 10 and the heatsink 11 and which is surrounded by the sealing member 3, the following material and medium are placed: a composite material COM (also referred to as a liquid crystal gel or a liquid crystal elastomer), deformed by an electric field E formed between a lower electrode 2 (lower electrode 2 attached to a surface of the heatsink 11 that faces the heat source 10) attached to the heatsink 11 and an upper electrode 6 (upper electrode 6 attached to a surface of the heat source 10 that faces the heatsink 11) attached to the heat source 10, containing a polymer material PO and a liquid crystal material LC and a low-thermal conductivity medium 4 that has a thermal conductivity lower than the thermal conductivity of the composite material COM, which contains the polymer material PO and the liquid crystal material LC, when the thermal switch 7 is ON.

In this embodiment, a case where the first member is composed of the heatsink 11 and the second member is composed of the heat source 10 is described as an example. Without being limited to this, the first member may include the heatsink 11 and a substrate (not shown) and the second member may include the heat source 10 and a substrate (not shown). When the first member includes the heatsink 11 and the substrate, the lower electrode 2 may be formed on a surface of the substrate on the heatsink 11, the surface facing the heat source 10. When the second member includes the heat source 10 and the substrate, the upper electrode 6 may be formed on a surface of the substrate on the heat source 10, the surface facing the heatsink 11. The above substrates used are preferably thin substrates with high thermal conductivity. In the case of applying a vertical electric field for the purpose of forming the electric field E in an illustrated vertical direction as described in this embodiment, the above substrates used may be metal substrates.

In this embodiment, the lower electrode 2, which is attached to the heatsink 11, and the upper electrode 6, which is attached to the heat source 10, are formed from ITO (indium tin oxide). Without being limited to this, the lower electrode 2 and the upper electrode 6 may be formed from, for example, another electrically conductive material such as a metal material.

In this embodiment, the sealing member 3 used is a sealing member including spherical spacers with a diameter of about 10 μm. The size of the spherical spacers, the shape of a spacer, and the like are not particularly limited. A sealing member including no spherical spacers may be used.

In this embodiment, the liquid crystal material LC used is, but is not limited to, 5CB which is a non-polymerizable liquid crystal material. The liquid crystal material LC used may be a liquid crystal material of which the dielectric constant anisotropy (Δε) is positive or negative, that is, the dielectric constant anisotropy (Δε) is not 0. As the absolute value of the dielectric constant anisotropy (Δε) is larger, lower power consumption can be achieved by the reduction of a driving voltage. Therefore, a liquid crystal material of which the absolute value of the dielectric constant anisotropy (Δε) is large is preferably used.

In this embodiment, the polymer material PO is, but is not limited to, a polymer network formed using a mixture of a monofunctional liquid-crystal monomer represented by (Chemical Formula A) below and a difunctional polymer network-forming monomer represented by (Chemical Formula B) below mixed at a 1:1 weight ratio. The polymer material PO is not particularly limited and may be one capable of forming a polymer network in the composite material COM, which contains the polymer material PO and the liquid crystal material LC.

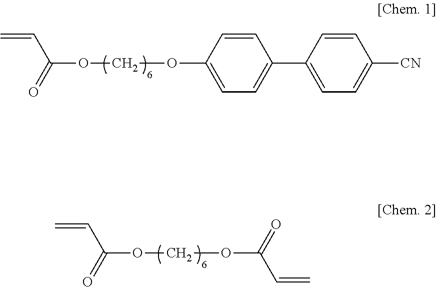

In this embodiment, the composite material COM, which contains the polymer material PO and the liquid crystal material LC, can be obtained as described below. A mixture of the non-polymerizable liquid crystal material (5CB)/a mixture of the liquid-crystal monomer of (Chemical Formula A) and the polymer network-forming monomer of (Chemical Formula B)/a photo-initiator (Irgacure 651) mixed at a weight ratio of (80/19.6/0.4) is agitated in an isotropic phase and is cooled to room temperature, whereby a precursor of the composite material COM, which contains the polymer material PO and the liquid crystal material LC, is obtained.

The precursor of the composite material COM, which contains the polymer material PO and the liquid crystal material LC, is dripped into the region which is located between the heat source 10 and the heatsink 11 and which is surrounded by the sealing member 3 so as to give a predetermined thickness (8 μm in the case of this embodiment), is heated, and is thereby formed. The precursor of the composite material COM, which contains the polymer material PO and the liquid crystal material LC, is exposed to light under a nitrogen atmosphere using an ultra-high-pressure mercury lamp such that the liquid-crystal monomer represented by (Chemical Formula A) and the polymer network-forming monomer represented by (Chemical Formula B) are polymerized, whereby the composite material COM, which contains the polymer material PO and the liquid crystal material LC, can be obtained.

As described above, in this embodiment, a method for obtaining the composite material COM, which contains the polymer material PO and the liquid crystal material LC, in such a manner that the non-polymerizable liquid crystal material, the monomers, and the photo-initiator are mixed together and the monomers are polymerized with light, which is an external stimulus, has been described as an example. Without being limited to this, the composite material COM, which contains the polymer material PO and the liquid crystal material LC, may be obtained in such a manner that, for example, the polymer material and the non-polymerizable liquid crystal material are mixed together under heating or in such a manner that the polymer material and the non-polymerizable liquid crystal material are mixed together using a solvent and the solvent is removed. Furthermore, the composite material COM, which contains the polymer material PO and the liquid crystal material LC, may be obtained in such a manner that the non-polymerizable liquid crystal material, the monomers, and a thermal initiator are mixed together and the monomers are polymerized with heat, which is an external stimulus.

Since the composite material COM, which contains the polymer material PO and the liquid crystal material LC, contains the liquid crystal material LC, which is the non-polymerizable liquid crystal material, the liquid crystal material LC is oriented at random as shown in FIG. 1A when the electric field E is not present between the lower electrode 2 and the upper electrode 6. However, when the electric field E is present between the lower electrode 2 and the upper electrode 6, the liquid crystal material LC is oriented along the electric field E formed in the illustrated vertical direction as shown in FIG. 1B. Incidentally, a horizontal alignment film (horizontal alignment layer) may be placed on at least one of the lower electrode 2 and the upper electrode 6 such that the liquid crystal material LC is oriented in an illustrated horizontal direction in a voltage-free state.

Thus, the composite material COM, which contains the polymer material PO and the liquid crystal material LC, is deformed by the electric field E formed between the lower electrode 2 and the upper electrode 6. In particular, the composite material COM, in which the liquid crystal material LC having positive dielectric constant anisotropy is used and which contains the polymer material PO and the liquid crystal material LC, is deformed so as to be larger in length in a direction (a vertical direction in this embodiment) in which the electric field E is formed when the electric field E is present between the lower electrode 2 and the upper electrode 6 than when the electric field E is not present therebetween.

In this embodiment, a case where the low-thermal conductivity medium 4 used is silicone oil having thermal conductivity (heat conductivity) lower than that of the composite material COM, which contains the polymer material PO and the liquid crystal material LC, when the thermal switch 7 is ON is described as an example. Without being limited to this, the low-thermal conductivity medium 4 used may be, for example, air or the like if the thermal conductivity thereof is lower than that of the composite material COM, which contains the polymer material PO and the liquid crystal material LC, when the thermal switch 7 is ON. The low-thermal conductivity medium 4 changes the area that maintains isolation between the heat source 10 and the heatsink 11 by the deformation of the composite material COM, which contains the polymer material PO and the liquid crystal material LC, as shown in FIGS. 1A and 1B and therefore is preferably a flowable substance such as gas or liquid.

In this embodiment, the low-thermal conductivity medium 4 is formed in such a manner that the silicone oil (a thermal conductivity of 0.13 W/mK) is dripped onto the composite material COM, which contains the polymer material PO and the liquid crystal material LC, in the region which is located between the heat source 10 and the heatsink 11 and which is surrounded by the sealing member 3 so as to give a thickness of 2 μm and is heated. Without being limited to this, the thickness of the silicone oil may be appropriately determined. Incidentally, the composite material COM, which contains the polymer material PO and the liquid crystal material LC, is gelatinous, is mainly composed of organic components, and therefore is extremely unlikely to be dissolved in the silicone oil, which is the low-thermal conductivity medium 4.

The area of the low-thermal conductivity medium 4 that maintains isolation between the heat source 10 and the heatsink 11 is larger when the thermal switch 7 is in the OFF state (little heat transfer state) as shown in FIG. 1A, that is, when the electric field E is not present between the lower electrode 2 and the upper electrode 6 than when the thermal switch 7 is in the ON state (much heat transfer state) as shown in FIG. 1B, that is, when the electric field E is present between the lower electrode 2 and the upper electrode 6.

When the thermal switch 7 is in the OFF state as shown in FIG. 1A, the low-thermal conductivity medium 4, which is lower in thermal conductivity than the composite material COM, which contains the polymer material PO and the liquid crystal material LC, inhibits heat Q from flowing from the heat source 10 to the heatsink 11 side. However, when the thermal switch 7 is in the ON state as shown in FIG. 1B, the composite material COM, which is higher in thermal conductivity than the low-thermal conductivity medium 4 and contains the polymer material PO and the liquid crystal material LC, allows heat Q to flow from the heat source 10 to the heatsink 11 side.

In this embodiment, the composite material COM, which contains the polymer material PO and the liquid crystal material LC, contains 5CB, which is the non-polymerizable liquid crystal material, as the liquid crystal material LC. The thermal conductivity of 5CB in a direction in which an electric field is applied is known to be about 0.24 W/mK at 25° C. The thermal conductivity of the composite material COM, which contains 5CB and also contains the polymer material PO and the liquid crystal material LC, during the application of an electric field is greater than 0.13 W/mK, which is the thermal conductivity of the silicone oil.

In this embodiment, a case where a voltage of 300 V is applied between the lower electrode 2 and the upper electrode 6 for the purpose of orienting the liquid crystal material LC along the electric field E formed in the illustrated vertical direction as shown in FIG. 1B is described as an example. If the liquid crystal material LC can be oriented along the electric field E formed in the illustrated vertical direction, a voltage of less than 300 V may be applied therebetween or a voltage of more than 300 V may be applied therebetween.

As described above, the composite material COM, which is contained in the thermal switch 7 and contains the polymer material PO and the liquid crystal material LC, allows the liquid crystal material LC to be oriented along the electric field E formed in the illustrated vertical direction, whereby the whole of the composite material COM, which contains the polymer material PO and the liquid crystal material LC, is deformed. That is, in the composite material COM, which contains the polymer material PO and the liquid crystal material LC, a portion which is partly bent is not formed. Therefore, the thermal switch 7 can be achieved such that the durability is high and the thermal conductivity can be controlled by an electric field.

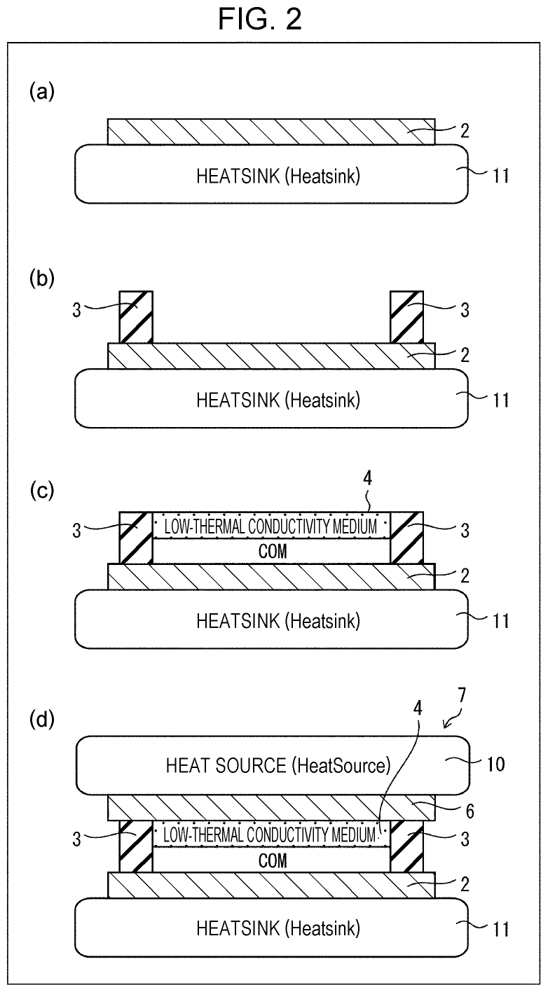

FIG. 2 is an illustration showing steps of manufacturing the thermal switch 7 shown in FIG. 1.

First, as shown in (a) of FIG. 2, the lower electrode 2 is formed on the heatsink 11. As shown in (b) of FIG. 2, the sealing member 3 is formed on the lower electrode 2 on the heatsink 11. In this embodiment, a frame of the sealing member 3 is formed so as to have a quadrangular shape with a side length of 2 cm. Without being limited to this, the shape and size of the frame of the sealing member 3 may be appropriately determined.

Next, as shown in (c) in FIG. 2, the precursor of the composite material COM, which contains the polymer material PO and the liquid crystal material LC, is dripped into the region surrounded by the sealing member 3 so as to give a predetermined thickness (8 μm in the case of this embodiment), is heated, and is thereby formed. The precursor of the composite material COM, which contains the polymer material PO and the liquid crystal material LC, is exposed to light under a nitrogen atmosphere using an ultra-high-pressure mercury lamp, whereby the composite material COM, which contains the polymer material PO and the liquid crystal material LC, is formed. Furthermore, the silicone oil is dripped onto the composite material COM, which contains the polymer material PO and the liquid crystal material LC, in the region surrounded by the sealing member 3 so as to give a thickness of 2 μm and is heated, whereby the low-thermal conductivity medium 4 is formed.

Next, as shown in (d) in FIG. 2, the lower electrode 2 and the upper electrode 6 are bonded together with the sealing member 3 therebetween so as to face each other. In this embodiment, the sealing member 3 used is a UV-curable sealing member. Therefore, the sealing member 3 is cured by irradiating the sealing member 3 with UV, whereby the thermal switch 7 is prepared.

In the case of using a UV-curable sealing member, the UV-curable sealing member used is preferably cured with light different in wavelength from that for the photo-initiator (Irgacure 651). A heat-curable sealing member may be used. In this case, the heat-curable sealing member used is preferably one cured at a temperature higher than the temperature of a step of forming the composite material COM, which contains the polymer material PO and the liquid crystal material LC, and the low-thermal conductivity medium 4.

A method for manufacturing the thermal switch 7 includes a step of forming the sealing member 3 on the heatsink 11 and a step of bonding the heat source 10 and the heatsink 11 together with the sealing member 3 therebetween such that the heat source 10 and the heatsink 11 face each other and also includes a step of forming the composite material COM, which is deformed by an electric field and contains the polymer material PO and the liquid crystal material LC, and the low-thermal conductivity medium 4, which is lower in thermal conductivity than the composite material COM, which is deformed by an electric field and contains the polymer material PO and the liquid crystal material LC, when the thermal switch 7 is ON, in the region surrounded by the sealing member 3 formed on the heatsink 11. According to the manufacturing method, the thermal switch 7 can be manufactured such that the durability is high and the thermal conductivity can be controlled by an electric field.

That is, the above manufacturing method includes a step of placing the heatsink 11, which is the first member, and the heat source 10, which is the second member, such that the heatsink 11 and the heat source 10 face each other, is a method for manufacturing the thermal switch 7 such that the thermal conductivity between the heat source 10 and the cooling pack body 110 is higher during the ON period than during the OFF period, and includes a step of forming the composite material COM, which is deformed by an electric field and contains the polymer material PO and the liquid crystal material LC, and the low-thermal conductivity medium 4, which is lower in thermal conductivity than the composite material COM, which is deformed by an electric field and contains the polymer material PO and the liquid crystal material LC, during the ON period, on at least one of the heat source 10 and the heatsink 11.

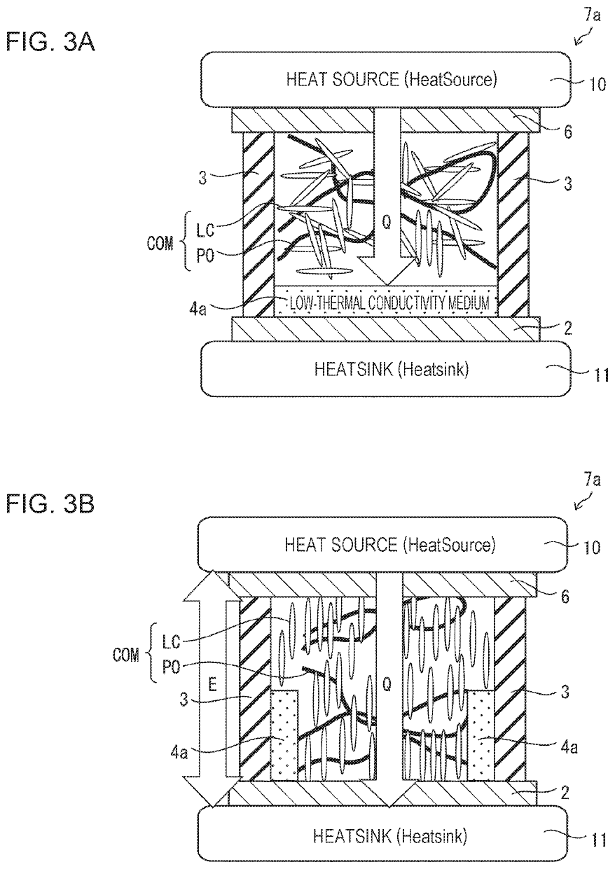

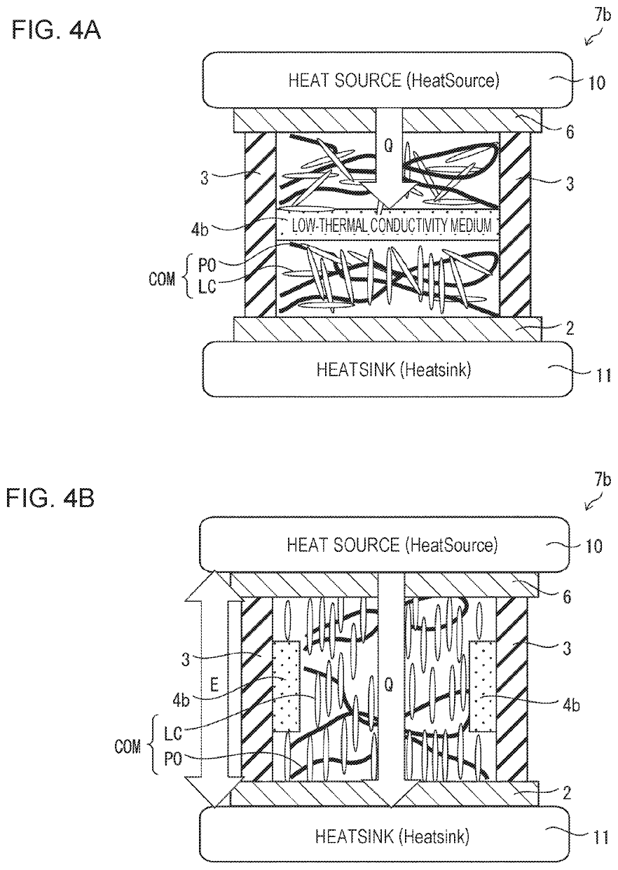

The thermal switches 7a and 7b, which are modifications of Embodiment 1, are described below with reference to FIGS. 3 and 4.

FIG. 3A is an illustration showing a case where the thermal switch 7a is in an OFF state (little heat transfer state). FIG. 3B is an illustration showing a case where the thermal switch 7a is in an ON state (much heat transfer state).

The thermal switch 7a differs from the thermal switch 7, in which the low-thermal conductivity medium 4 is placed on the heat source 10 side as shown in FIGS. 1 and 2, in that a low-thermal conductivity medium 4a is placed on the heatsink 11 side.

The thermal switch 7a, which is not shown, can be prepared as described below.

First, a sealing member 3 is formed on an upper electrode 6 of a heat source 10 and a precursor of the composite material COM, which contains the polymer material PO and the liquid crystal material LC, is dripped into a region surrounded by the sealing member 3 on the heat source 10 so as to give a predetermined thickness (8 μm in the case of this embodiment), is heated, and is thereby formed. The precursor of the composite material COM, which contains the polymer material PO and the liquid crystal material LC, is exposed to light under a nitrogen atmosphere using an ultra-high-pressure mercury lamp, whereby the composite material COM, which contains the polymer material PO and the liquid crystal material LC, is formed. Furthermore, the silicone oil is dripped onto the composite material COM, which contains the polymer material PO and the liquid crystal material LC, in the region surrounded by the sealing member 3 on the heat source 10 so as to give a thickness of 2 μm and is heated, whereby the low-thermal conductivity medium 4a is formed. Next, a lower electrode 2 and an upper electrode 6 are bonded together with the sealing member 3 therebetween so as to face each other. In this embodiment, the sealing member 3 used is a UV-curable sealing member. Therefore, the sealing member 3 is cured by irradiating the sealing member 3 with UV, whereby the thermal switch 7a is prepared.

The composite material COM, which is contained in the thermal switch 7a and contains the polymer material PO and the liquid crystal material LC, allows the liquid crystal material LC to be oriented along an electric field E formed in an illustrated vertical direction, whereby the whole of the composite material COM, which contains the polymer material PO and the liquid crystal material LC, is deformed. That is, in the composite material COM, which contains the polymer material PO and the liquid crystal material LC, a portion which is partly bent is not formed. Therefore, the thermal switch 7a can be achieved such that the durability is high and the thermal conductivity can be controlled by an electric field.

FIG. 4A is an illustration showing a case where the thermal switch 7b is in an OFF state (little heat transfer state). FIG. 4B is an illustration showing a case where the thermal switch 7b is in an ON state (much heat transfer state).

The thermal switch 7b differs from the above-mentioned thermal switches 7 and 7b in that a low-thermal conductivity medium 4b is located at substantially the midpoint between a heat source 10 and a heatsink 11. In this embodiment, a case where the low-thermal conductivity medium 4b is located at substantially the midpoint between the heat source 10 and the heatsink 11 is described as an example. Without being limited to this, the low-thermal conductivity medium 4b may be placed out of contact with a lower electrode 2 and an upper electrode 6.

The thermal switch 7b, which is not shown, can be prepared as described below.

First, a sealing member 3 is formed on the lower electrode 2 of the heatsink 11. Next, a precursor of the composite material COM, which contains the polymer material PO and the liquid crystal material LC, is dripped into a region surrounded by the sealing member 3 on the heatsink 11 so as to give a predetermined thickness (4 μm in the case of this embodiment), is heated, and is thereby formed. The precursor of the composite material COM, which contains the polymer material PO and the liquid crystal material LC, is exposed to light under a nitrogen atmosphere using an ultra-high-pressure mercury lamp, whereby the composite material COM, which contains the polymer material PO and the liquid crystal material LC, is formed. Furthermore, the silicone oil is dripped onto the composite material COM, which contains the polymer material PO and the liquid crystal material LC, in the region surrounded by the sealing member 3 on the heatsink 11 so as to give a thickness of 2 μm and is heated, whereby the low-thermal conductivity medium 4b is formed. Thereafter, the composite material COM, which contains the polymer material PO and the liquid crystal material LC, is formed on the low-thermal conductivity medium 4b in the region surrounded by the sealing member 3 on the heatsink 11 so as to give a predetermined thickness (4 μm in the case of this embodiment). Next, the lower electrode 2 and the upper electrode 6 are bonded together with the sealing member 3 therebetween so as to face each other. In this embodiment, the sealing member 3 used is a UV-curable sealing member. Therefore, the sealing member 3 is cured by irradiating the sealing member 3 with UV, whereby the thermal switch 7b is prepared.

In order to prevent the precursor of the composite material COM, which contains the polymer material PO and the liquid crystal material LC, from mixing with the silicone oil as the low-thermal conductivity medium 4b when the composite material COM, which contains the polymer material PO and the liquid crystal material LC, is formed on the low-thermal conductivity medium 4b in the region surrounded by the sealing member 3 on the heatsink 11, the composite material COM, which contains the gelled polymer material PO, which is obtained by mixing, for example, a polymer material and a non-polymerizable liquid crystal material under heating, and the liquid crystal material LC, is preferably formed on the low-thermal conductivity medium 4b. Alternatively, after the precursor of the composite material COM, which contains the polymer material PO and the liquid crystal material LC, is provided between separately prepared glass substrates and a monomer is polymerized by UV irradiation, the obtained composite material COM, which contains the polymer material PO and the liquid crystal material LC, is stripped from the glass substrates and may be provided on the low-thermal conductivity medium 4b.

The composite material COM, which is contained in the thermal switch 7b and contains the polymer material PO and the liquid crystal material LC, allows the liquid crystal material LC to be oriented along an electric field E formed in an illustrated vertical direction, whereby the whole of the composite material COM, which contains the polymer material PO and the liquid crystal material LC, is deformed. That is, in the composite material COM, which contains the polymer material PO and the liquid crystal material LC, a portion which is partly bent is not formed. Therefore, the thermal switch 7b can be achieved such that the durability is high and the thermal conductivity can be controlled by an electric field.

In this embodiment, a case where a vertical electric field is applied for the purpose of forming the electric field E between the lower electrode 2 and the upper electrode 6 in the illustrated vertical direction has been described above as an example. Without being limited to this, a horizontal electric field may be applied for the purpose of forming an electric field E between a first electrode and second electrode attached to any one of a first member and a second member in an illustrated horizontal direction as described in an embodiment below.

### Embodiment 2

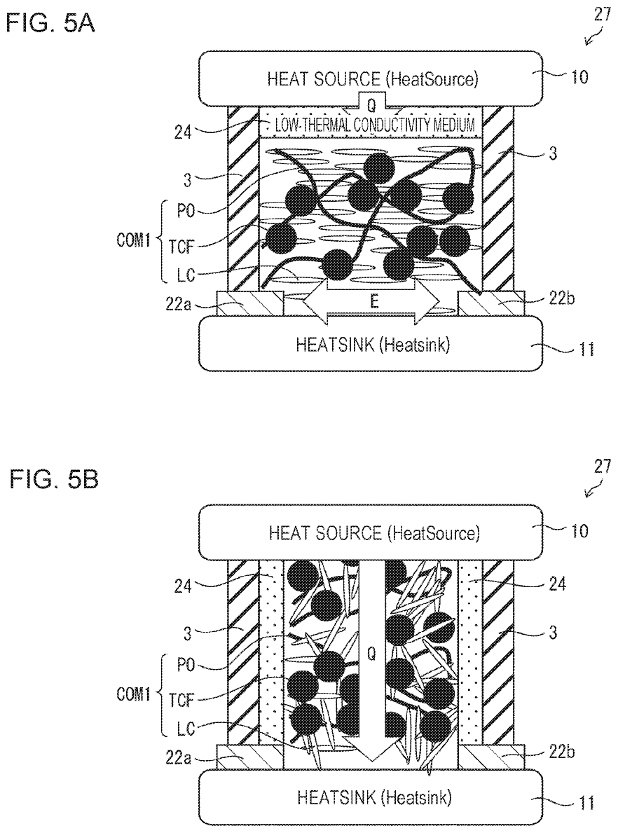

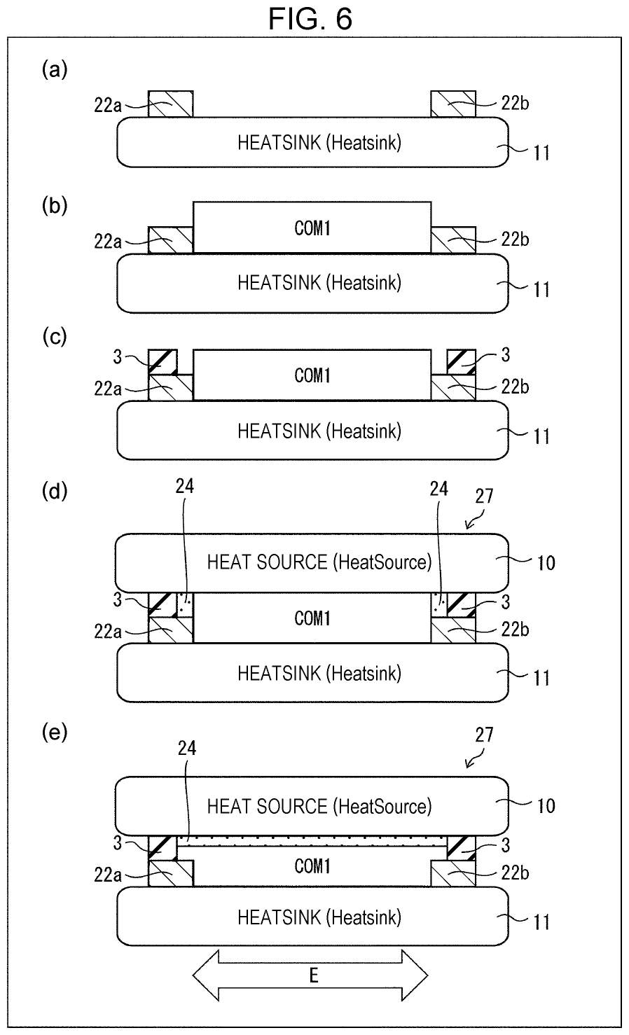

Next, Embodiment 2 of the present invention is described with reference to FIGS. 5 and 6. A thermal switch 27 according to this embodiment differs from Embodiment 1 in that the thermal switch 27 contains a thermally conductive filler-containing composite material (a composite material containing a thermally conductive filler TCF, a polymer material PO, and a liquid crystal material LC) COM1 containing a thermally conductive filler TCF. Another configuration is as described in Embodiment 1. For convenience of description, members having the same function as that of the members shown in the figures of Embodiment 1 are given the same reference numerals and will not be described in detail.

FIG. 5A is an illustration showing a case where the thermal switch 27 is in an OFF state (little heat transfer state). FIG. 5B is an illustration showing a case where the thermal switch 27 is in an ON state (much heat transfer state).

In this embodiment, a precursor of the thermally conductive filler-containing composite material COM1 can be obtained in such a manner that the thermally conductive filler TCF is added to the precursor of the composite material COM, containing the polymer material PO and the liquid crystal material LC, described above in Embodiment 1 such that the volume ratio of the precursor of the composite material COM, which contains the polymer material PO and the liquid crystal material LC, to the thermally conductive filler TCF is 7/3, followed by agitation in an isotropic phase and then cooling to room temperature.

The precursor of the thermally conductive filler-containing composite material COM1 is dripped into a region which is located between a heat source 10 and a heatsink 11 and which is surrounded by a sealing member 3 so as to give a predetermined thickness (10 μm to 12 μm in the case of this embodiment), is heated, and is thereby formed. The thermally conductive filler-containing composite material COM1 can be obtained in such a manner that the precursor of the thermally conductive filler-containing composite material COM1 is exposed to light under a nitrogen atmosphere using an ultra-high-pressure mercury lamp.

The thermally conductive filler TCF is preferably insulating and preferably has higher thermal conductivity. Therefore, in this embodiment, the thermally conductive filler TCF used is made of aluminum nitride particles (AlN particles) with an average particle size of 40 nm to 100 nm. The material or particle size of the thermally conductive filler TCF is not limited to this. The aluminum nitride particles exhibit a thermal conductivity of 180 W/mK to 230 W/mK.

In this embodiment, a method for obtaining the thermally conductive filler-containing composite material COM1 in such a manner that a non-polymerizable liquid crystal material, a monomer, a photo-initiator, and the thermally conductive filler are mixed together and the monomer is polymerized with light, which is an external stimulus, has been described as an example. Without being limited to this, the thermally conductive filler-containing composite material COM1 may be obtained in such a manner that, for example, a polymer material, the non-polymerizable liquid crystal material, and the thermally conductive filler are mixed together under heating or in such a manner that the polymer material, the non-polymerizable liquid crystal material, and the thermally conductive filler TCF are mixed together using a solvent and the solvent is removed. Furthermore, the thermally conductive filler-containing composite material COM1 may be obtained in such a manner that the non-polymerizable liquid crystal material, the monomer, a thermal initiator, and the thermally conductive filler are mixed together and the monomer is polymerized with heat, which is an external stimulus. Alternatively, after the precursor of the thermally conductive filler-containing composite material COM1 is provided between separately prepared glass substrates and the monomer is polymerized by UV irradiation, the obtained thermally conductive filler-containing composite material COM1 is stripped from the glass substrates and may be used.

In this embodiment, a case where a low-thermal conductivity medium 24 used is air, which is lower in thermal conductivity than the thermally conductive filler-containing composite material COM1 when the thermal switch 27 is ON, is described as an example. The thermal switch 27 may be, but is not limited to, one that is lower in thermal conductivity than the thermally conductive filler-containing composite material COM1 when the thermal switch 27 is ON. Incidentally, the thermal conductivity of air is 0.024 W/mK.

The thermal switch 27 includes the heatsink 11 and the heat source 10. The heatsink 11 is equipped with a first electrode 22a and a second electrode 22b. In this embodiment, the first electrode 22a and the second electrode 22b are formed from ITO (indium tin oxide). Without being limited to this, the first electrode 22a and the second electrode 22b may be formed from, for example, another electrically conductive material such as a metal material. The interelectrode distance between the first electrode 22a and the second electrode 22b is, but is not limited to, 10 μm and the electrode width of each of the first electrode 22a and the second electrode 22b is, but is not limited to, 5 μm. The first electrode 22a and the second electrode 22b are also referred to as interdigital electrodes. As shown in FIG. 5A, a horizontal electric field can be applied for the purpose of forming an electric field E between the first electrode 22a and the second electrode 22b in an illustrated horizontal direction.

The thermally conductive filler-containing composite material COM1 contains the liquid crystal material LC, which is the non-polymerizable liquid crystal material. Therefore, as shown in FIG. 5A, when the electric field E is present between the first electrode 22a and the second electrode 22b in the illustrated horizontal direction, the liquid crystal material LC is oriented along the electric field E formed in the illustrated horizontal direction. However, as shown in FIG. 5B, when the electric field E is not present between the first electrode 22a and the second electrode 22b, the liquid crystal material LC is oriented at random.

Thus, the thermally conductive filler-containing composite material COM1 is deformed by the electric field E formed between the first electrode 22a and the second electrode 22b. In particular, the thermally conductive filler-containing composite material COM1 is deformed so as to be larger in length in an illustrated vertical direction when the electric field E is not present between the first electrode 22a and the second electrode 22b than when the electric field E is present therebetween.

The area of the low-thermal conductivity medium 24 that maintains isolation between the heat source 10 and the heatsink 11 is larger when the thermal switch 27 is in the OFF state (little heat transfer state) as shown in FIG. 5A, that is, when the electric field E is present between the first electrode 22a and the second electrode 22b, than when the thermal switch 27 is in the ON state (much heat transfer state) as shown in FIG. 5B, that is, when the electric field E is not present between the first electrode 22a and the second electrode 22b.

When the thermal switch 27 is in the OFF state as shown in FIG. 5A, the low-thermal conductivity medium 24, which is lower in thermal conductivity than the thermally conductive filler-containing composite material COM1, inhibits heat Q from flowing from the heat source 10 to the heatsink 11 side. However, when the thermal switch 27 is in the ON state as shown in FIG. 5B, the thermally conductive filler-containing composite material COM1, which is higher in thermal conductivity than the low-thermal conductivity medium 24, allows heat Q to flow from the heat source 10 to the heatsink 11 side.

In this embodiment, a case where a voltage of 300 V is applied between the first electrode 22a and the second electrode 22b for the purpose of orienting the liquid crystal material LC along the electric field E formed in the illustrated horizontal direction as shown in FIG. 5A is described as an example. If the liquid crystal material LC can be oriented along the electric field E formed in the illustrated horizontal direction, a voltage of less than 300 V may be applied therebetween or a voltage of more than 300 V may be applied therebetween.

As described above, the thermally conductive filler-containing composite material COM1, which is contained in the thermal switch 27, allows the liquid crystal material LC to be oriented along the electric field E formed in the illustrated horizontal direction or oriented at random, whereby the whole of the thermally conductive filler-containing composite material COM1 is deformed. That is, in the thermally conductive filler-containing composite material COM1, a portion which is partly bent is not formed. Therefore, the thermal switch 27 can be achieved such that the durability is high and the thermal conductivity can be controlled by an electric field.

The thermally conductive filler-containing composite material COM1, which is contained in the thermal switch 27, contains the aluminum nitride particles, which have high thermal conductivity, as the thermally conductive filler TCF. Therefore, the thermal conductivity thereof when the thermal switch 27 is in the ON state as shown in FIG. 5B is three times or more higher than the thermal conductivity when the thermal switch 27 is in the OFF state as shown in FIG. 5A.

Incidentally, a thin film with low surface energy may be formed on a surface of at least one of the heat source 10 and the heatsink 11 that is in contact with the thermally conductive filler-containing composite material COM1.

FIG. 6 is an illustration showing steps of manufacturing the thermal switch 27 shown in FIG. 5.

First, as shown in (a) of FIG. 6, the first electrode 22a and the second electrode 22b are formed on the heatsink 11. As shown in (b) of FIG. 6, a precursor of the thermally conductive filler-containing composite material COM1 is dripped onto the heatsink 11, is heated, and is thereby formed. The precursor of the thermally conductive filler-containing composite material COM1 is exposed to light under a nitrogen atmosphere using an ultra-high-pressure mercury lamp, whereby the thermally conductive filler-containing composite material COM1 is formed. Thereafter, as shown in (c) of FIG. 6, the sealing member 3 is formed over the first electrode 22a and second electrode 22b on the heatsink 11. Incidentally, the sealing member 3 is formed such that the sealing member 3 is spaced from the thermally conductive filler-containing composite material COM1 at a predetermined distance. In this embodiment, a frame of the sealing member 3 is formed so as to have a quadrangular shape with a side length of 2 cm. Without being limited to this, the shape and size of the frame of the sealing member 3 may be appropriately determined.

Next, as shown in (d) of FIG. 6, the heat source 10 and the heatsink 11 are bonded together with the sealing member 3 therebetween so as to face each other. In this embodiment, the sealing member 3 used is a UV-curable sealing member. Therefore, the sealing member 3 is cured by irradiating the sealing member 3 with UV, whereby the thermal switch 27 is prepared. Incidentally, air filled in a space present between the sealing member 3 and the thermally conductive filler-containing composite material COM1 corresponds to the low-thermal conductivity medium 24. Section (d) of FIG. 6 is an illustration showing a case where the thermal switch 27 is in the ON state. Section (e) of FIG. 6 is an illustration showing a case where the thermal switch 27 is in the OFF state.

In this embodiment, a case where the thermally conductive filler-containing composite material COM1 is used to apply a horizontal electric field for the purpose of forming the electric field E between the first electrode 22a and the second electrode 22b in the illustrated horizontal direction has been described above as an example. Without being limited to this, the thermally conductive filler-containing composite material COM1 can be preferably used to apply a horizontal electric field for the purpose of forming the electric field E between the lower electrode 2 attached to the heatsink 11 and the upper electrode 6 attached to the heat source 10 in the illustrated horizontal direction as described above in Embodiment 1.

In this embodiment, a case where a first member is composed of the heatsink 11 and a second member is composed of the heat source 10 is described as an example. Without being limited to this, the first member may include the heatsink 11 and a substrate (not shown) and the second member may include the heat source 10 and a substrate (not shown). When the first member includes the heatsink 11 and the substrate, the first electrode 22a and the second electrode 22b may be formed on a surface of the substrate on the heatsink 11, the surface facing the heat source 10. The substrate used is preferably a thin substrate with high thermal conductivity and any electrically conductive substrate such as a metal substrate cannot be used. On the other hand, the substrate included in the second member, which is provided with none of the first electrode 22a and the second electrode 22b, may be an electrically conductive substrate such as a metal substrate. In a case where a horizontal electric field is applied for the purpose of forming the electric field E in the illustrated horizontal direction as described in this embodiment and the substrate included in the second electrode is a metal substrate, the interelectrode distance between the first electrode 22a and the second electrode 22b, the electrode width of each of the first electrode 22a and the second electrode 22b, the distance between the metal substrate included in the second member and the first electrode 22a, and the distance between the metal substrate included in the second member and the second electrode 22b are preferably optimized such that a desired electric field is applied.

In this embodiment, the thermal switch 27 is exemplified as an example of an apparatus containing the thermally conductive filler-containing composite material (the composite material containing the thermally conductive filler TCF, the polymer material PO, and the liquid crystal material LC) COM1, which contains the thermally conductive filler TCF. Without being limited to this, the apparatus containing the thermally conductive filler-containing composite material COM1 may be, for example, a cooling device or a display device.

### Embodiment 3

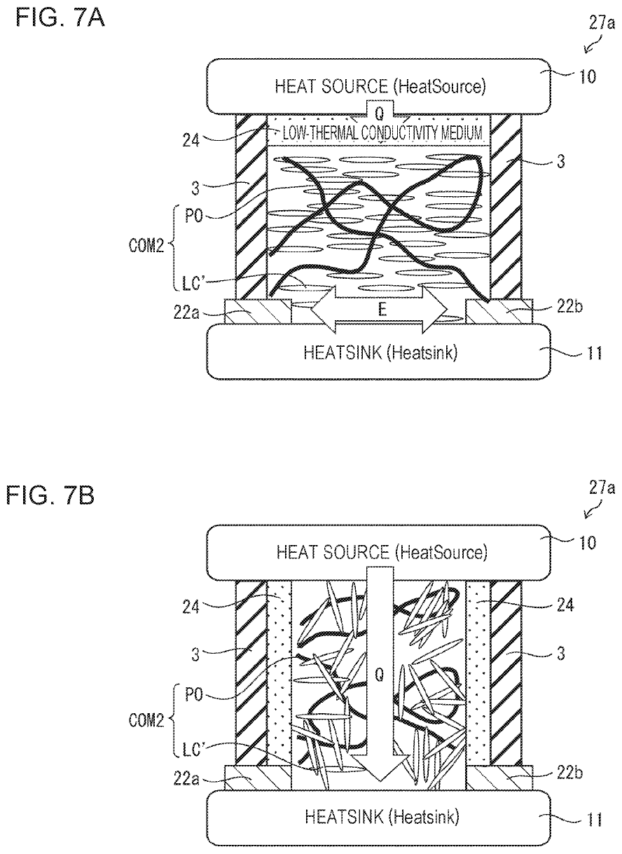

Next, Embodiment 3 of the present invention is described with reference to FIG. 7. A thermal switch 27a according to this embodiment contains a composite material COM2 containing a polymer material PO and a liquid crystal material LC′. The liquid crystal material LC′ in a liquid crystal state differs from the liquid crystal material LC contained in the composite material COM, containing the polymer material PO and the liquid crystal material LC, described above in Embodiment 1 and the liquid crystal material LC contained in the thermally conductive filler-containing composite material COM1 described above in Embodiment 2 in that the value of the dielectric constant anisotropy (Δε) is 100 or more. Another configuration is as described in Embodiments 1 and 2. For convenience of description, members having the same function as that of the members shown in the figures of Embodiments 1 and 2 are given the same reference numerals and will not be described in detail.

FIG. 7A is an illustration showing a case where the thermal switch 27a is in an OFF state (little heat transfer state). FIG. 7B is an illustration showing a case where the thermal switch 27 is in an ON state (much heat transfer state).

In Embodiments 1 and 2 described above, the liquid crystal material LC contained in the composite material COM containing the polymer material PO and the liquid crystal material LC and the liquid crystal material LC contained in the thermally conductive filler-containing composite material COM1 are 5CB. The liquid crystal material LC′, which is contained in the composite material COM2, which is contained in the thermal switch 27a according to this embodiment and contains the polymer material PO and the liquid crystal material LC′, is a non-polymerizable liquid crystal material (a non-polymerizable liquid crystal material containing six fluorine groups and a 1,3-dioxane unit in a mesogenic core) of which the value of the dielectric constant anisotropy (Δε) is 100 or more in a liquid crystal state and which is represented by (Chemical Formula C) below (for the liquid crystal material LC′, see Adv. Mater. 2017, 1702354).

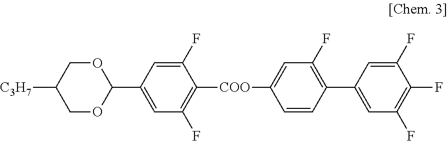

In this embodiment, since the liquid crystal material LC′, of which the value of the dielectric constant anisotropy (Δε) is large, is used, the composite material COM2, which contains the polymer material PO and the liquid crystal material LC′, can be deformed with about half or less the driving voltage necessary in Embodiments 1 and 2.

Thus, the reduction in power consumption of the thermal switch 27a can be achieved.

The liquid crystal material LC′, which is contained in the composite material COM2, which contains the polymer material PO and the liquid crystal material LC′, is such that the change in relative dielectric constant a temperature change of 1° C. at a temperature between −40° C. and 200° C. is preferably 0.5/° C. or more, more preferably 5/° C. or more, and further more preferably 10/° C. or more. The liquid crystal material LC′, which is contained in the composite material COM2, which contains the polymer material PO and the liquid crystal material LC′, is such that the change in relative dielectric constant a temperature change of 1° C. at a temperature which is 10° C. or more lower than the clearing point of a liquid crystal material and which is between −40° C. and 200° C. is preferably 0.5/° C. or more, more preferably 5/° C. or more, and further more preferably 10/° C. or more. As the electric flux density of the liquid crystal material LC′ or the temperature dependence of the dielectric constant thereof is larger, an electrocaloric effect that causes the release or absorption of heat due to a change in entropy is larger.

The composite material COM2, which contains the polymer material PO containing the liquid crystal material LC′ and the liquid crystal material LC′, has the electrocaloric effect, which causes the release or absorption of heat due to a change in entropy. When the thermal switch 27a is in the OFF state as shown in FIG. 7A, that is, when an electric field E is formed between a first electrode 22a and second electrode 22b attached to a heatsink 11 or is large, the composite material COM2, which contains the polymer material PO and the liquid crystal material LC′, releases heat. When the thermal switch 27a is in the ON state as shown in FIG. 7B, that is, when the electric field E between the first electrode 22a and the second electrode 22b, which are attached to the heatsink 11, is zero or small, the composite material COM2, which contains the polymer material PO and the liquid crystal material LC′, absorbs heat.

When the thermal switch 27a is in the OFF state as shown in FIG. 7A, a low-thermal conductivity medium 24 which is lower in thermal conductivity than the composite material COM2, which contains the polymer material PO and the liquid crystal material LC′, inhibits heat Q from flowing from a heat source 10 to the heatsink 11 side. However, when the thermal switch 27a is in the ON state as shown in FIG. 7B, the composite material COM2, which is higher in thermal conductivity than the low-thermal conductivity medium 24 and contains the polymer material PO and the liquid crystal material LC′, allows heat Q to flow from the heat source 10 to the heatsink 11 side. As described above, the composite material COM2, which contains the polymer material PO and the liquid crystal material LC′, is in an endothermic state when the thermal switch 27a is in the ON state. Therefore, the composite material COM2, which contains the polymer material PO and the liquid crystal material LC′, enables heat Q to flow more efficiently from the heat source 10 to the heatsink 11 side and the thermal switch 27a can be achieved so as to have higher cooling efficiency.

In this embodiment, a case where the liquid crystal material LC′, of which the value of the dielectric constant anisotropy (Δε) is large, is a liquid crystal material of which the value of the dielectric constant anisotropy (Δε) is 100 or more has been described as an example. Without being limited to this, a liquid crystal material of which the value of the dielectric constant anisotropy (Δε) is 30 or more allows the composite material COM2, which contains the polymer material PO and the liquid crystal material LC′, to be in an endothermic state when the thermal switch 27a is in the ON state. Therefore, the thermal switch 27a can be achieved so as to have higher cooling efficiency.

### Embodiment 4

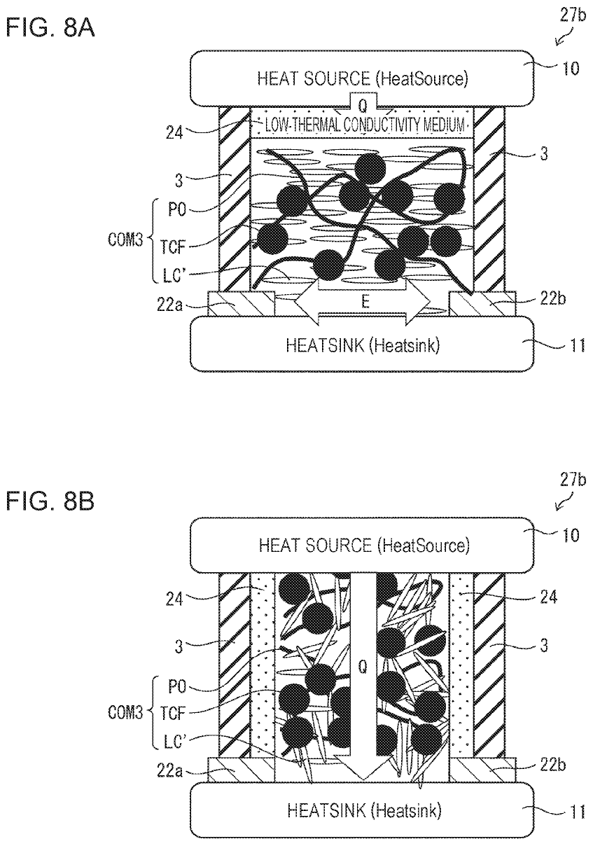

Next, Embodiment 4 of the present invention is described with reference to FIG. 8. A thermal switch 27b according to this embodiment contains a thermally conductive filler-containing composite material (a composite material which contains a thermally conductive filler TCF and which contains a polymer material PO and a liquid crystal material LC′) COM3. The liquid crystal material LC′ in a liquid crystal state differs from the liquid crystal material LC contained in the thermally conductive filler-containing composite material COM1 described above in Embodiment 2 in that the value of the dielectric constant anisotropy (Δε) is 100 or more. Another configuration is as described in Embodiment 2. For convenience of description, members having the same function as that of the members shown in the figures of Embodiment 2 are given the same reference numerals and will not be described in detail.

FIG. 8A is an illustration showing a case where the thermal switch 27b is in an OFF state (little heat transfer state). FIG. 8B is an illustration showing a case where the thermal switch 27b is in an ON state (much heat transfer state).

In Embodiment 2 described above, the liquid crystal material LC contained in the thermally conductive filler-containing composite material COM1 is 5CB. The liquid crystal material LC′, which is contained in the thermally conductive filler-containing composite material COM3, which is contained in the thermal switch 27b according to this embodiment, is a non-polymerizable liquid crystal material (a non-polymerizable liquid crystal material containing six fluorine groups and a 1,3-dioxane unit in a mesogenic core) of which the value of the dielectric constant anisotropy (Δε) is 100 or more in a liquid crystal state and which is represented by (Chemical Formula C) below.

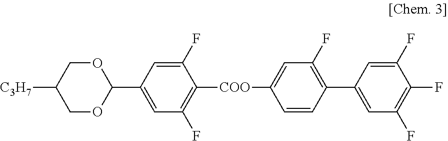

In this embodiment, since the liquid crystal material LC′, of which the value of the dielectric constant anisotropy (Δε) is large, is used, the thermally conductive filler-containing composite material COM3 can be deformed with about half or less the driving voltage necessary in Embodiments 1 and 2. Thus, the reduction in power consumption of the thermal switch 27b can be achieved.

The thermally conductive filler-containing composite material COM3, which is contained in the thermal switch 27b, contains aluminum nitride particles having high thermal conductivity as the thermally conductive filler TCF. Therefore, the thermal conductivity thereof when the thermal switch 27b is in the ON state as shown in FIG. 8B is three times or more higher than the thermal conductivity when the thermal switch 27b is in the OFF state as shown in FIG. 8A.

When the thermal switch 27b is in the OFF state as shown in FIG. 8A, a low-thermal conductivity medium 24 which is lower in thermal conductivity than the thermally conductive filler-containing composite material COM3 inhibits heat Q from flowing from a heat source 10 to the heatsink 11 side. However, when the thermal switch 27b is in the ON state as shown in FIG. 8B, the thermally conductive filler-containing composite material COM3, which is higher in thermal conductivity than the low-thermal conductivity medium 24, allows heat Q to flow from the heat source 10 to the heatsink 11 side. The thermally conductive filler-containing composite material COM3, which contains the liquid crystal material LC′, has an electrocaloric effect that causes the release or absorption of heat due to a change in entropy. Therefore, when the thermal switch 27b is in the ON state, the thermally conductive filler-containing composite material COM3 is in an endothermic state; hence, the thermally conductive filler-containing composite material COM3 enables heat Q to flow more efficiently from the heat source 10 to the heatsink 11 side and the thermal switch 27a can be achieved so as to have higher cooling efficiency.

### Embodiment 5

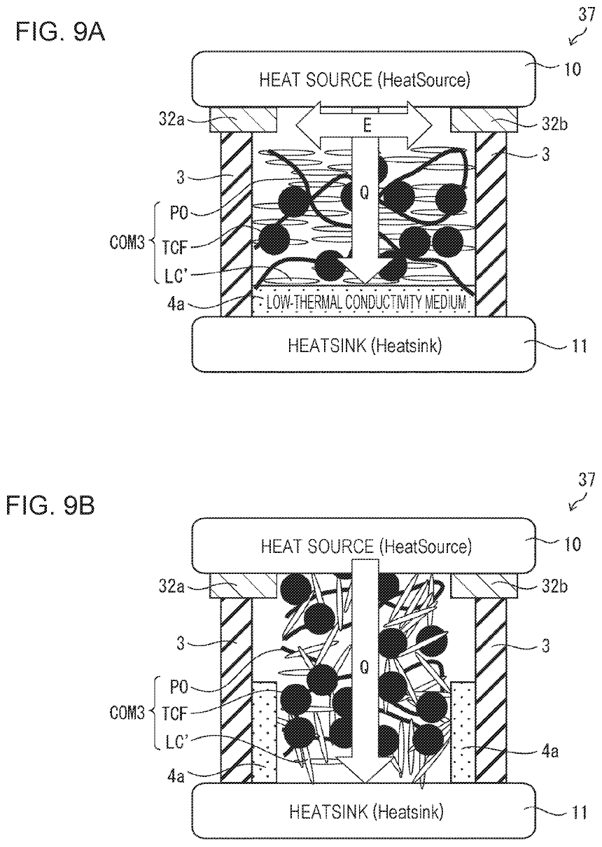

Next, Embodiment 5 of the present invention is described with reference to FIG. 9. A thermal switch 37 according to this embodiment differs from the thermal switch 27b according to Embodiment 4 in that a first electrode 32a and a second electrode 32b are attached to a heat source 10 and a low-thermal conductivity medium 4a used is silicone oil. Another configuration is as described in Embodiment 4. For convenience of description, members having the same function as that of the members shown in the figures of Embodiment 4 are given the same reference numerals and will not be described in detail.

FIG. 9A is an illustration showing a case where the thermal switch 37 is in an OFF state (little heat transfer state). FIG. 9B is an illustration showing a case where the thermal switch 37 is in an ON state (much heat transfer state).

In this embodiment, a liquid crystal material LC′ of which the value of the dielectric constant anisotropy (Δε) is large is used and therefore a thermally conductive filler-containing composite material COM3 can be deformed with about half or less the driving voltage necessary in Embodiments 1 and 2. Thus, the reduction in power consumption of the thermal switch 37 can be achieved.

The thermally conductive filler-containing composite material COM3, which is contained in the thermal switch 37, contains aluminum nitride particles having high thermal conductivity as a thermally conductive filler TCF. Therefore, the thermal conductivity thereof when the thermal switch 37 is in the ON state as shown in FIG. 9B is three times or more higher than the thermal conductivity when the thermal switch 37 is in the OFF state as shown in FIG. 9A.

When the thermal switch 37 is in the OFF state as shown in FIG. 9A, the low-thermal conductivity medium 4a, which is lower in thermal conductivity than the thermally conductive filler-containing composite material COM3, inhibits heat Q from flowing from the heat source 10 to the heatsink 11 side. However, when the thermal switch 37 is in the ON state as shown in FIG. 9B, the thermally conductive filler-containing composite material COM3, which is higher in thermal conductivity than the low-thermal conductivity medium 4a, allows heat Q to flow from the heat source 10 to the heatsink 11 side. The thermally conductive filler-containing composite material COM3, which contains the liquid crystal material LC′, has an electrocaloric effect that causes the release or absorption of heat due to a change in entropy. Therefore, when the thermal switch 37 is in the ON state, the thermally conductive filler-containing composite material COM3 is in an endothermic state; hence, the thermally conductive filler-containing composite material COM3 enables heat Q to flow more efficiently from the heat source 10 to the heatsink 11 side and the thermal switch 37 can be achieved so as to have higher cooling efficiency.

In this embodiment, a case where a first member is composed of the heatsink 11 and a second member is composed of the heat source 10 is described as an example. Without being limited to this, the first member may include the heatsink 11 and a substrate (not shown) and the second member may include the heat source 10 and a substrate (not shown). When the second member includes the heat source 10 and the substrate, the first electrode 32a and the second electrode 32b may be formed on a surface of the substrate under the heat source 10, the surface facing the heatsink 11. The above substrate used is preferably a thin substrate with high thermal conductivity and any electrically conductive substrate such as a metal substrate cannot be used. On the other hand, the substrate included in the first member, which is provided with none of the first electrode 32a and the second electrode 32b, is formed may be an electrically conductive substrate such as a metal substrate. In a case where a horizontal electric field is applied for the purpose of forming an electric field E in an illustrated horizontal direction as described in this embodiment and the substrate included in the first electrode is a metal substrate, the interelectrode distance between the first electrode 32a and the second electrode 32b, the electrode width of each of the first electrode 32a and the second electrode 32b, the distance between the metal substrate included in the first member and the first electrode 32a, and the distance between the metal substrate included in the first member and the second electrode 32b are preferably optimized such that a desired electric field is applied.

### Embodiment 6

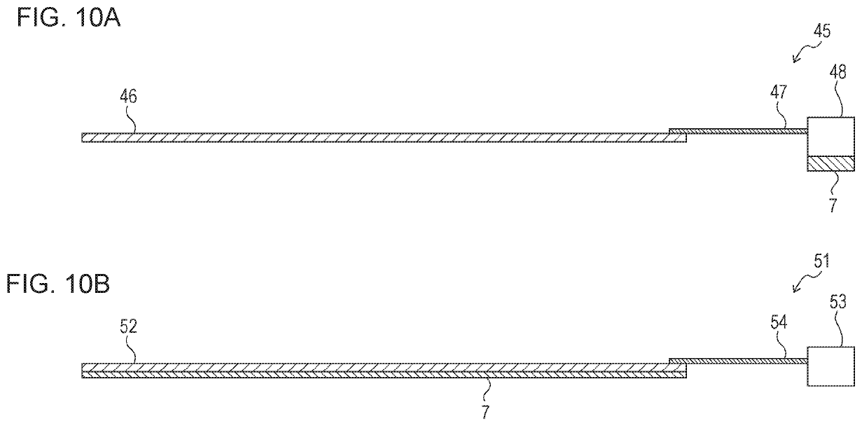

Next, Embodiment 6 of the present invention is described with reference to FIG. 10. Display devices 45 and 51 according to this embodiment include the thermal switch 7. For convenience of description, members having the same function as that of the members shown in the figures in Embodiments 1 to 5 are given the same reference numerals and will not be described in detail.

FIG. 10A is an illustration showing the schematic configuration of the display device 45, which includes the thermal switch 7.

The display device 45 includes a display panel 46, a control circuit 48, a wiring line 47 electrically connecting a wiring line of the display panel 46 to a terminal of the control circuit 48, and the thermal switch 7. In this case, the control circuit 48, which generates heat, is a heat source 10 that is a second member of the thermal switch 7 and a heat dissipation plate or the like can be used as a heatsink 11 that is a first member of the thermal switch 7. Incidentally, a circuit (not shown) controlling electrodes in the thermal switch 7 may be included in the control circuit 48 or may be placed separately from the control circuit 48.

The heat generated from the control circuit 48 can be dissipated in such a manner that the thermal switch 7 is put into an ON state (much heat transfer state) when the control circuit 48 is operated, that is, in conformity with the timing that the control circuit 48 is generating heat. On the other hand, the thermal switch 7 can be put into an OFF state (little heat transfer state) in the OFF period of the display panel 46 that is the non-operation period of the control circuit 48, that is, in conformity with the timing that the control circuit 48 generates no heat.

In this embodiment, a case where the display device 45 includes the thermal switch 7 is described as an example. Without being limited to this, the display device 45 may have a configuration including any of the thermal switch 7a, the thermal switch 7b, the thermal switch 27, the thermal switch 27a, the thermal switch 27b, and the thermal switch 37 instead of the thermal switch 7.

FIG. 10B is an illustration showing the schematic configuration of the display device 51, which includes the thermal switch 7.

The display device 51 includes a display panel 52, a control circuit 53, a wiring line 54 electrically connecting a wiring line of the display panel 52 to a terminal of the control circuit 53, and the thermal switch 7. In this case, the display panel 52, which generates heat, is a heat source 10 that is a second member of the thermal switch 7 and a heat dissipation plate or the like can be used as a heatsink 11 that is a first member of the thermal switch 7. Incidentally, a circuit (not shown) controlling electrodes in the thermal switch 7 may be included in the control circuit 53 or may be placed separately from the control circuit 53.

The heat generated from the display panel 52 can be dissipated in such a manner that the thermal switch 7 is put into an ON state (much heat transfer state) when the display panel 52 is operated, that is, in conformity with the timing that the display panel 52 is generating heat. On the other hand, the thermal switch 7 can be put into an OFF state (little heat transfer state) in the OFF period of the display panel 52 that is the non-operation period of the display panel 52, that is, in conformity with the timing that the display panel 52 generates no heat.

In general, displays are likely to deteriorate in high-temperature environments. In a display device according to this embodiment, deterioration is suppressed because the temperature of a display is unlikely to rise even in a high-temperature environment. Members for displays sacrifice optical characteristics and the like in some cases for the purpose of enabling the members to be used in a high-temperature environment. A member used in a display device according to this embodiment has little concern about deterioration in a high-temperature environment; hence, a member for displays can be selected from a wider range and a member having high characteristics such as optical characteristics can be selected.

### (Appendix)

The present invention is not limited to the above-mentioned embodiments. Various modifications can be made within the scope specified in the claims. An embodiment obtained by appropriately combining technical means disclosed in different embodiments is included in the technical scope of the present invention. In addition, a novel technical feature can be formed by combining technical means disclosed in the embodiments.

### INDUSTRIAL APPLICABILITY

The present disclosure can be applied to a thermal switch, a method for manufacturing the thermal switch, a thermally conductive filler-containing composite material, an apparatus containing the composite material, and a display device.

### REFERENCE SIGNS LIST

2 Lower electrode
3 Sealing member
4 Low-thermal conductivity medium
4a Low-thermal conductivity medium
4b Low-thermal conductivity medium
6 Upper electrode
7 Thermal switch
7a Thermal switch
7b Thermal switch
10 Heat source (second member)
11 Heatsink (first member)
22a First electrode
22b Second electrode
24 Low-thermal conductivity medium
27 Thermal switch
27a Thermal switch
27b Thermal switch
32a First electrode
32b Second electrode
37 Thermal switch
45 Display device
51 Display device
E Electric field
LC Liquid crystal material
LC′ Liquid crystal material
PO Polymer material
TCF Thermally conductive filler
COM Composite material containing polymer material and liquid crystal material
COM1 Thermally conductive filler-containing composite material
COM2 Composite material containing polymer material and liquid crystal material
COM3 Thermally conductive filler-containing composite material

1. A thermal switch comprising:
a first member and second member placed so as to face each other,
the thermal conductivity between the first member and the second member being higher during an ON period than during an OFF period,
wherein a composite material which is deformed by an electric field formed between a plurality of electrodes attached to at least one of the first member and the second member and which contains a polymer material and a liquid crystal material and
a low-thermal conductivity medium with a thermal conductivity lower than the thermal conductivity of the composite material during the ON period
are placed between the first member and the second member.

2. The thermal switch according to claim 1, wherein the thermal conductivity between the first member and the second member is changed in such a manner that the low-thermal conductivity medium changes the area that maintains isolation between the first member and the second member by the deformation of the composite material.

3. The thermal switch according to claim 1, wherein the composite material contains a thermally conductive filler.

4. The thermal switch according to claim 1, wherein the liquid crystal material, which is contained in the composite material, in a liquid crystal state is such that the value of the dielectric constant anisotropy (Δε) is 30 or more.

5. The thermal switch according to claim 1, wherein the liquid crystal material, which is contained in the composite material, is such that the change in relative dielectric constant a temperature change of 1° C. at a temperature between −40° C. and 200° C. is 0.5/° C. or more.

6. The thermal switch according to claim 1, wherein the electrodes include a lower electrode and an upper electrode,
the lower electrode is attached to the first member, and
the upper electrode is attached to the second member.

7. The thermal switch according to claim 1, wherein the electrodes include a first electrode and a second electrode and
the first electrode and the second electrode are attached to at least one of the first member and the second member.

8. The thermal switch according to claim 1, wherein the low-thermal conductivity medium is gas or silicone oil.

9. The thermal switch according to claim 3, wherein the thermally conductive filler is aluminum nitride particles.

10. The thermal switch according to claim 1, wherein one of the first member and the second member is a heat source and the other of the first member and the second member is a heatsink.

11. The thermal switch according to claim 1, wherein the first member and the second member are bonded together with a sealing member therebetween and
the composite material and the low-thermal conductivity medium are placed in a region which is located between the first member and the second member and which is surrounded by the sealing member.

12. A thermally conductive filler-containing composite material according to claim 1, wherein a composite material containing a polymer material PO and a liquid crystal material contains a thermally conductive filler.

13. The thermally conductive filler-containing composite material according to claim 12, wherein the composite material is deformed by an electric field.

14. The thermally conductive filler-containing composite material according to claim 12, wherein the liquid crystal material in a liquid crystal state is such that the value of the dielectric constant anisotropy (Δε) is 30 or more.

15. The thermally conductive filler-containing composite material according to claim 12, wherein the liquid crystal material is such that the change in relative dielectric constant a temperature change of 1° C. at a temperature between −40° C. and 200° C. is 0.5/° C. or more.

16. The thermally conductive filler-containing composite material according to claim 12, wherein the thermally conductive filler is aluminum nitride particles.

17. An apparatus containing the thermally conductive filler-containing composite material according to claim 12.

18. A display device comprising the thermal switch according to claim 1.

19. A method for manufacturing a thermal switch, comprising:
a step of placing a first member and a second member such that the first member and the second member face each other, the thermal conductivity between the first member and the second member being higher during an ON period than during an OFF period; and
a step of forming a composite material which is deformed by an electric field and which contains a polymer material and a liquid crystal material and a low-thermal conductivity medium with a thermal conductivity lower than the thermal conductivity of the composite material during the ON period on any one of the first member and the second member.
